(19) United States
(12) Patent Application Publication
(10) Pub. No.: US 2014/0062647 A1
(43) Pub. Date: Mar. 6, 2014

(54) CONTINUOUSLY TRANSPOSED CONDUCTOR

(71) Applicants: Thomas Trimmel, Seebenstein (AT); Martin Trimmel, Seebenstein (AT)

(72) Inventors: Thomas Trimmel, Seebenstein (AT); Martin Trimmel, Seebenstein (AT)

(73) Assignee: ASTA ELEKTRODRAHT GMBH, Oed/Wiener Neustadt (AT)

(21) Appl. No.: 14/001,317

(22) PCT Filed: Feb. 23, 2012
(86) PCT No.: PCT/EP12/53048

§ 371 Date: Oct. 24, 2013

(30) Foreign Application Priority Data
Feb. 24, 2011 (AT) A252/2011

(51) Int. Cl. H01F 27/36; H05K 9/00

(52) U.S. Cl. CPC H01F 27/365; H05K 9/00
USPC 336/84 C; 174/36

(57) ABSTRACT

In order to be able to industrially produce a transposed conductor with jointly transposed partial conductors located one atop the other and in order to be able to further process such a transposed conductor to form a winding, the invention proposes that two adjacent single conductors (11) located one atop the other be connected to one another on their contact surfaces (16) in a non-positive fashion, preferably that they be adhered to one another.

The present invention relates to a continuously transposed conductor comprising a plurality of individual, electrically insulated single conductors, in which two or more single conductors disposed one above the other are combined into a group of single conductors and transposed together, as well as a transformer comprising a winding made of such a transposed conductor.

A continuously transposed conductor is understood to be a transposed conductor that is manufactured in long lengths, for example, lengths of a few thousand meters are not rare, and that are subsequently processed to form a winding of an electrical machine, for example, a transformer winding. During the winding process, the transposed conductors experience a strong degree of curvature. In contrast, winding rods or Roebel cables of short length are manually produced and combined to form a winding for an electrical machine (for example, an electric motor or a generator) in that the straight rods are placed in grooves on the rotor and the axial ends of the rods are subsequently connected to one another in a certain fashion in order to form the winding. Such a winding rod is thus also produced from a series of single conductors transposed with one another, with a finished winding rod never being warped or bent in any way in the course of its further processing such that its transposed partial conductors or groups of partial conductors remain in position throughout. Thus, as a matter of principle, different problems occur in the further processing of continuously transposed conductors and winding rods, for which reason they cannot be directly compared to one another.

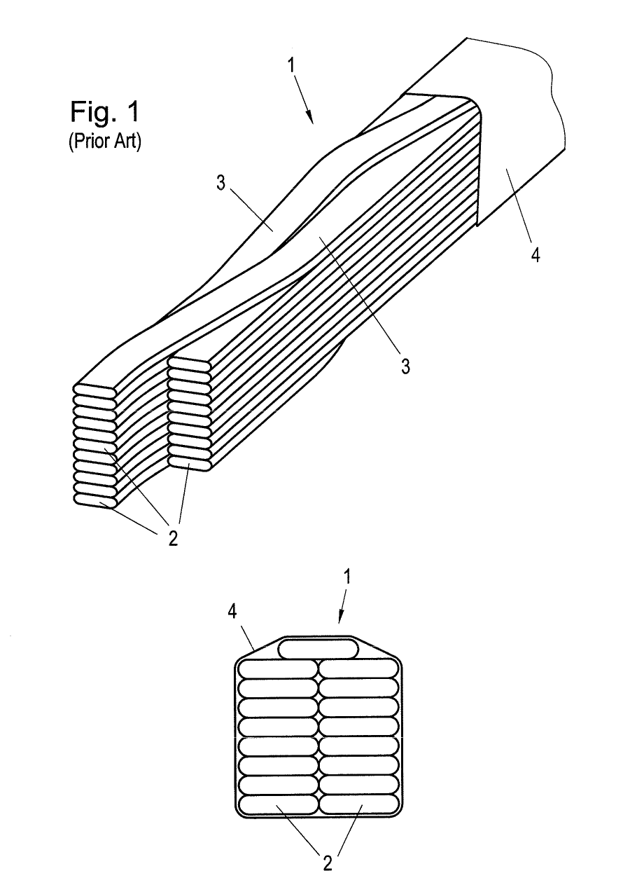

It is known that electromagnetic axial fields (longitudinal fields) occur in transformers, primarily in the main part (central part) of the winding, which induce eddy currents in the conductors of the winding that lead to eddy current losses. Eddy current losses reduce the efficiency of the transformer, but also cause undesirably high local temperatures, which in turn can cause damage to the winding insulation. By the use of known continuously transposed conductors, such eddy current losses can be reduced. Such transposed conductors comprise a bundle of individual, insulated partial conductors that are individually transposed one against the other, for example, according to the Roebel principle, as is shown, for example, in FIG. 1. Such contenuously transposed conductors are known, for example, from EP 746 861 B1 and are produced in a mechanical and automated fashion with lengths of a few thousand meters and are wound onto drums for shipment. Transposed conductors are particularly distinguished by the fact that they are sufficiently flexible that they can be wound in order to produce windings.

For winding rods and Roebel cables, AT 309 590 B discloses providing the transposition in such a way that two adjacent partial conductors are always transposed together. In addition to compensating for the longitudinal field by transposition, this measure is also intended to compensate for the radial field inside a groove, which is already detrimental. Roebel cables, which continue to be primarily manufactured manually in that short partial conductors are manually transposed on special workbenches by a worker, can thus be produced in a simple manner even when two adjacent partial conductors are jointly transposed. Roebel cables, however, are not wound; rather, a winding is “built” from a plurality of Roebel cables by connecting the ends of the Roebel cables correspondingly.

However, demands on modern transformers are constantly increasing, on the one hand, with regard to size and output and, on the other hand, with regard to efficiency and reduction of losses caused by, for example, eddy current. Particularly in the case of very large, high-performance transformers, significant undesired eddy current losses occur due to the magnetic fields. Moreover, the reduction of the hotspot temperature, voltage properties, and fill factor have a great deal of significance in the design of transformer windings.

In currently known transposed conductors, it is not possible to improve the properties mentioned above by physical limits in the transposed conductor production process due to their geometry and manufacturing options. The number of possible single conductors for transposed conductors that can be transposed into a transposed conductor is limited by the so-called transposition factor. The transposition factor f_{D} is described by the following formula as a function of the inner diameter of the transformer winding, the number of single conductors of the transposed conductor, and the width of the single conductor:

$${f}_{D} = \frac{WD \cdot π}{n \cdot {b}_{1}}$$

The variables represent

WD smallest winding diameter

n number of single conductors

b₁ with of a single conductor

Current production technology allows transposed conductors to be produced up to a mini-mum transposition factor of f₀=5, with the number of single conductors, the wire width, and winding diameter being dependent on one another. This limitation of the transposition factor by production technology limits the ability of transposed conductors to be produced with an increasing number of single conductors.

In a transformer winding with conventional transposed conductors, the voltage distribution is also problematic because potential differences between the parallel transposed conductors cause undesired capacities to occur. Moreover, significant eddy current losses, and therefore also high temperatures in the transposed conductor and the winding, occur.

When a plurality of single conductors is used that are transposed together as a bundle of single conductors to form a transposed conductor, the resulting eddy current losses and thus the hotspot temperatures can be reduced. Such a transposed conductor is known, for example, from EP 133 220 A2, in which cables comprised of a group of round single conductors are transposed to form an electrical conductor. A similar conductor is disclosed by U.S. Pat. No. 4,431,860A, in which the single conductors of the individual cables are transposed into one another again. This allows the number of single conductors to be increased and the physical limitation of the transposition factor to still be maintained at five. However, when round single conductors are used, as is the case in EP 133 220 A2, a poor fill factor results, causing the cross section of the transposed conductor to become undesirably large with the prespecified copper cross section. In one embodiment of the cables, the round single conductors may be deformed in a rectangular fashion in the packet which, although it improves the fill factor somewhat, also requires an additional process step, thus making production more expensive.

However, the transposed conductors disclosed by EP 133 220 A2 and U.S. Pat. No. 4,431,860A have the distinct disadvantage of expensive production because a partial conductor must first be produced from a number of single wires by transposing the single wires and only then are these compact partial conductors transposed to form a transposed conductor. This results in at least one additional laborious process step, along with all the associated disadvantages such as storage and handling of the single wires and partial conductors, various transposition systems, longer production times, etc. For this reason, the use of such transposed conductors according to the prior art has more or less been avoided in practice. However, the transposition of the single wires allowed a compact, internally stable partial conductor to be produced in which the single conductors cannot shift relative to one another and that is therefore suitable for subsequent transposition to form a transposed conductor. Only in this manner has it been possible up to now to produce transposed conductors with partial conductors made of multiple single conductors.

When jointly transposing partial conductors located loosely one atop the other, it is possible for the individual partial conductors to shift relative to one another, which would make the finished transposed conductor unusable. Up to now, it was not possible for two or more single conductors located one atop the other to be jointly transposed in one process step of a continuous manufacturing process for producing a continuously transposed conductor. Such a production of a transposed conductor was therefore up to now not controllable from a production standpoint. Moreover, a transposed conductor with partial conductors having single conductors lying loosely one atop the other cannot be processed into a winding because the single conductors could shift relative to one another due to their different radial lengths that result in the winding or the radially inner single conductor could bulge. Such a transposed conductor therefore also cannot be further processed to form a winding.

One object of the present invention is therefore to disclose a transposed conductor with jointly transposed single conductors located one atop the other that enables a more simple production of the transposed conductor and that may be further processed to form a winding.

This object is attained according to the invention in that two adjacent single conductors located one atop the other are connected in a non-positive fashion on their contact surfaces, preferably adhered to one another. The non-positive connection of two single conductors on their contact surfaces before being transposed to form a transposed conductor is significantly simpler from a production standpoint than transposing such single conductors to form a partial conductor. At the same time, this non-positive connection ensures that the transposed conductor, as usual, may be wound into a winding in an upright fashion because this prevents the single conductors located on different radii from shifting relative to one another and prevents the radially interior single conductor from bulging during winding.

It is particularly advantageous for all adjacent single conductors disposed one atop the other to be connected to one another in a non-positive fashion on each of their contact surfaces, preferably adhered to one another.

If the single conductors in the group of single conductors are disposed in an n×n or n×m arrangement, it is advantageous for two adjacent single conductors located next to one another to also be connected to one another in a non-positive fashion, preferably to be adhered to one another, because this achieves a particularly stable partial conductor that may be safely processed to form a transposed conductor that can also be safely wound. This is improved even further if all adjacent single conductors disposed next to one another are connected to one another in a non-positive fashion on each of their contact surfaces, preferably adhered to one another.

The non-positive connection of the single conductors may be simplified if the edges of the single conductors are embodied in a rounded fashion and the roundings of the edges of a single conductor of a group of single conductors that limit a contact surface between two single conductors located next to one another or one atop the other are embodied with a smaller radius than the radii of the roundings of the outer edges of the group of single conductors. This allows a greater available area to be attained for connecting the single conductors and also allows for a secure connection of the single conductors.

If the thickness of the insulation layer in a transposed conductor according to the invention is embodied between 0.03 and 0.08 mm, preferably 0.06 mm, the fill factor of such a transposed conductor can be improved because this allows the increase in the amount of lacquer caused by the greater number of single conductors in the transposed conductor to be effectively counteracted by a reduction in the lacquer layer.

The voltage distribution in a known transformer winding with conventional transposed conductors wound in a parallel fashion is considerably poorer than when transposed conductors according to the invention with separate single conductors are used. In conventional transformer windings, potential differences in the parallel transposed conductors cause capacities to occur that do not occur if a transposed conductor according to the invention with separate single conductors is used because the single conductors in the overall bundle are transposed with one another. Moreover, unifying the parallel transposed conductors to form one transposed conductor with separate single conductors results in an improvement of the fill factor, and the outer dimensions of the transformer become more compact. Thus, the use of a transposed conductor according to the invention in a transformer winding is particularly advantageous.

The present invention shall be described below with reference to FIGS. 1 to 4, which show advantageous embodiments by way of example that are in no way limiting. Shown are:

FIG. 1 a conventional transposed conductor according to the prior art,

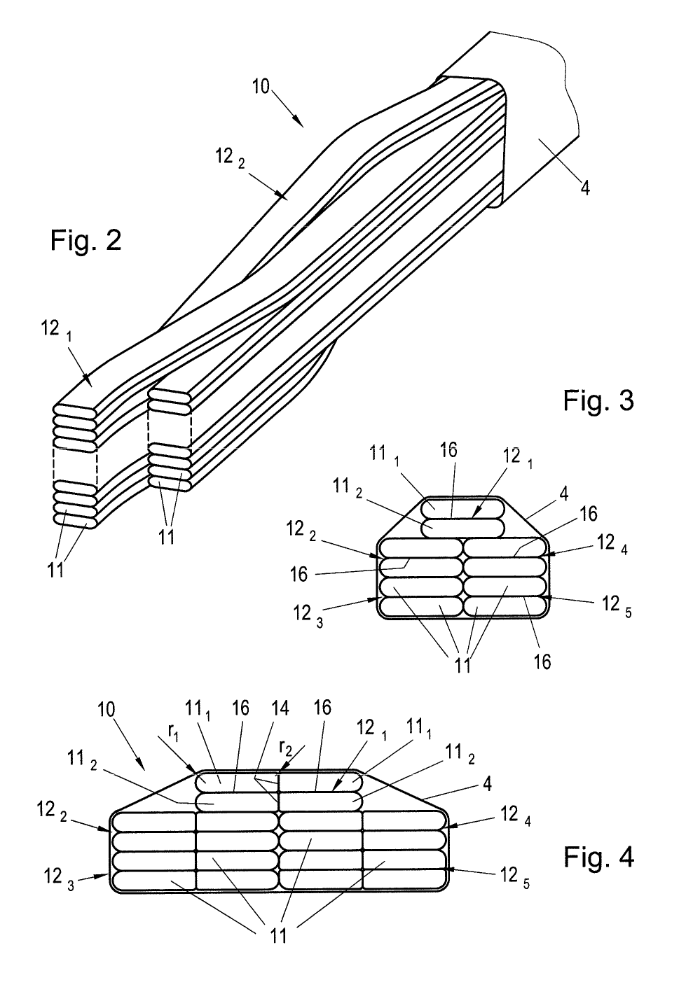

FIG. 2 a transposed conductor according to the invention having a group of single conductors with single conductors disposed one atop the other,

FIG. 3 a cross section of a transposed conductor according to the invention, and

FIG. 4 a cross section of a transposed conductor according to the invention having a group of single conductors with an n×n arrangement of single conductors.

FIG. 1 shows a sufficiently known transposed conductor 1 comprising a number of electrically insulated single conductors 2 that are disposed in two single conductor stacks 3. As is known, the single conductors 2 are transposed in such a way that they change position from the uppermost position to the lowest position. A single conductor 2 has a rectangular cross section and rounded edges. In order to guarantee that the bundle of single conductors holds together to form a transposed conductor 1 or in order to protect the transposed conductor, a wrapping 4 may be provided using a woven tape, a strip of paper, or the like.

A transposed conductor 10 according to the invention is shown in FIGS. 2 and 3 that comprises a plurality of individual electrically insulated single conductors 11. In this transposed conductor 10, two single conductors 11 located one atop the other are combined to form a single conductor group 12 and are jointly transposed. In this context, “one atop the other” means that, given a rectangular cross section of the single conductor, the single conductors 11 are disposed resting against one another on their longitudinal sides on a contact surface 16. However, a single conductor group 12 could also comprise more than two single conductors 11 disposed one atop the other and therefore multiple contact surfaces 16 between the respective single conductors 11.

The transposed conductor 10 may in turn be surrounded by a wrapping 4, for example, to protect the single conductors 11 during transport or to stabilize the transposed conductor 10.

In a transformer winding, the transposed conductor 10 is wound in an upright fashion; as a result, a single conductor 11₁ of the single conductor group 12₁ is located on a larger winding radius than the single conductor 11₂ of the same group. The same applies to the other single conductor groups 12₂ to 12₅. In order to prevent the single conductors 11₁, 11₂ of the single conductor group 12 from shifting relative to one another during transposition or winding and in order to prevent the radially interior single conductor 11₂ from bulging during winding, the single conductors 11₁, 11₂ of the single conductor group 12 are connected to one another in a non-positive fashion on their contact surfaces 16 (relative to the winding in the radial direction); preferably, the single conductors 11₁, 11₂ are adhered to one another on their contact surfaces 16.

In another possible embodiment of the transposed conductor 10 according to the invention, a single conductor group 12 comprises a plurality of single conductors 11 disposed next to one another and one atop the other, for example, in an n×n arrangement of single conductors 11, as shown in FIG. 4, or in an n×m arrangement of single conductors 11. The single conductors 11 located next to one another therefore rest against one another on a second contact surface 14 and the single conductors 11 located one atop the other rest against one another on a first contact surface 16. The single conductors 11 of the single conductor group 12 located next to one another can also be connected in a non-positive fashion on their contact surfaces 14 (relative to the winding in the axial direction), preferably adhered to one another. This also ensures that the single conductors 11 located next to one another do not shift relative to one another in the case of a lateral displacement in the transposition process and the individual conductors 11 therefore remain in their intended position within the single conductor group 12.

Alternately or additionally to the non-positive connection on the narrow sides of the single conductors (the contact surfaces 14), provision may also be made for the radii r₂ of the roundings of the edges that limit the contact surfaces 14 of the adjacent single conductors 11 of the single conductor group 12 are smaller than the roundings of the outer edges of the single conductor group, as is shown in FIG. 4. The “outer” edges in this case are the edges of the resulting rectangular (or quadratic) cross section of the single conductor group 12. In principle, it may also be sufficient to round off only one of these edges or one of these edges on each single conductor 11 with a smaller radius r₂. From the standpoint of the fill factor, however, it is better for all of these edges of the single conductor 11 to be rounded off with a smaller radius r₂. The small radii r₂ therefore result in a sufficiently large contact surface 14 that prevents the individual conductors 11 from shifting over or under one another during the transposition process in which the single conductor group 12 must be laterally shifted. In contrast, with the large radii r₁ that are necessary on the outside, the single conductors could very easily slide against one another on the radii and it would be very simple for the single conductors 11 to slide over or under one another, which would make the transposition process virtually impossible.

In addition, it is possible for one or all edges that limit the contact surfaces 16 between two adjacent single conductors 11 located one atop the other to be embodied with a smaller radius r₂, as is shown in FIG. 4 on the single conductor group 12₅.

The provision of smaller radii r₁ on the edges limiting the contact surfaces 14, 16 also has the advantage that a larger effective area is provided thereby for the non-positive connection, for example, a larger adhesion area.

A transposed conductor 10 may also be used particularly advantageously in a transformer winding, with a transposed conductor 10 embodied according to the invention being able to replace two conventional transposed conductors (for example, according to FIG. 1) wound in a parallel fashion because the transposed conductor 10 according to the invention contains considerably more, for example, twice as many, single conductors 11.

A transposed conductor 10 according to the invention has a lower fill factor than a conventional transposed conductor with the same cross section because each single conductor 11 must be insulated and, due to the larger number of single conductors 11, more insulation is naturally present in the cross section. According to the applicable norm, the insulation layer of a single conductor 11 is 0.1 mm at grade 1 and 0.15 mm at grade 2. In today's transposed conductors, only quality grade 1 is generally used. In order to improve the fill factor in a transposed conductor 10 according to the invention while maintaining the same cross section, provision may be made for the thickness of the insulation layer to be reduced, preferably to a range of 0.03 to 0.08 mm, preferably also 0.06 mm.

1. A continuously transposed conductor comprising a plurality of individual, electrically insulated single conductors (11), with two or more single conductors (11) disposed one atop the other being combined to form a single conductor group (12) and being jointly transposed, characterized in that two adjacent single conductors (11) of a single conductor group (12) disposed one atop the other are connected to one another in a non-positive fashion, preferably adhered to one another on their contact surfaces (16).

2. The continuously transposed conductor according to claim 1, characterized in that all adjacent single conductors (11) of a single conductor group (12) disposed one atop the other are connected to one another on each of their contact surfaces (16) in a non-positive fashion, preferably adhered to one another.

3. The continuously transposed conductor according to claim 1, characterized in that the single conductors (11) in the single conductor group (16) are disposed in an n×n or n×m arrangement and two adjacent single conductors (11) disposed next to one another are connected to one another on their contact surfaces (14) in a non-positive fashion, preferably adhered to one another.

4. The continuously transposed conductor according to claim 3, characterized in that all adjacent single conductors (11) of the single conductor group (12) disposed next to one another are connected to one another on their respective contact surfaces (14) in a non-positive fashion, preferably adhered to one another.

5. The continuously transposed conductor according to one of claim 1, characterized in that the edges of the single conductors (11) are designed in a rounded-off fashion and the roundings of the edges of a single conductor (11) of a single conductor group (12) that limit a contact surface (14, 16) between two single conductors (11) disposed next to one another or one atop the other are designed with a smaller radius (r₂) than the radii (r₁) of the roundings of the outer edges of the single conductor group (12).

6. The continuously transposed conductor according to claim 1, characterized in that the thickness of the insulation layer of a single conductor (11) is embodied between 0.03 and 0.08 mm, preferably 0.06 mm.

7. A transformer having a winding made of a continuously transposed conductor (10) according to claim 1.
